(19) United States
(12) Patent Application Publication
(10) Pub. No.: US 2014/0052396 A1
(43) Pub. Date: Feb. 20, 2014

(54) Device and Method for Measuring the Capacity Degradation of a Battery

(71) Applicants: Shan Shan Jin, Daejeon (KR); Jae Hwan Lim, Daejeon (KR); Chong Hun Han, Seoul (KR); Sung Woo Cho, Incheon (KR); Hyun Seok Chung, Seoul (KR)

(72) Inventors: Shan Shan Jin, Daejeon (KR); Jae Hwan Lim, Daejeon (KR); Chong Hun Han, Seoul (KR); Sung Woo Cho, Incheon (KR); Hyun Seok Chung, Seoul (KR)

(73) Assignee: SK INNOVATION CO., LTD., Seoul (KR)

(21) Appl. No.: 14/114,040

(22) PCT Filed: Apr. 28, 2011
(86) PCT No.: PCT/KR11/03131

§ 371 Date: Oct. 25, 2013

(51) Int. Cl. G01R 31/36

(52) U.S. Cl. CPC G01R 31/3679
USPC 702/63

(57) ABSTRACT

Provided are an apparatus and a method for measuring battery capacity fade. The apparatus for measuring battery capacity fade includes: at least one battery used in a hybrid vehicle, a plug-in hybrid electric vehicle or an electric vehicle; a sensing unit sensing current, voltage and temperature of the at least one battery; a data processing unit measuring voltage and current data from the sensing unit if the current is constant current in a charging period and state of charge (SOC) is in a predetermined region; and a calculating unit setting at least two points on the voltage data and applying the voltage data corresponding to the at least two points to an equivalent circuit model of the at least one batter, to calculate faded capacity.

### TECHNICAL FIELD

The present invention relates to an apparatus and a method for measuring battery capacity fade, and more particularly, to an apparatus and a method for measuring battery capacity fade used in a hybrid vehicle, a plug-in hybrid electric vehicle or an electric vehicle.

### BACKGROUND ART

Recently, since it has become important for vehicles to consider the environmental impact, a plug-in hybrid electric vehicle (PHEV) or an electric vehicle (EV) attracts attentions. For such a PHEV or an EV, technical development for a battery is especially important. This is because that such a PHEV or an EV requires a higher capacity and power of a battery than other environmentally-friendly vehicles.

Usually, a battery has a lifespan and its power decreases since internal resistance increases as it is used. In addition, its capacity is also decreased. It is important to measure the performance of a battery since deterioration in the performance may cause deterioration in fuel efficiency and performance of a plug-in hybrid electric vehicle.

Presently, patent applications already exist relating to battery capacity fade and power deterioration, for example, US Patent Application Publication Nos. 2004/0220758 and 2006/0113959.

According to the Patent Documents, however, measurement can be done only in a particular current pattern (e.g., a particular constant current pattern) such as charging, and thus is not practical to use. Accordingly, required is a technique in which capacity fade and power deterioration can be measure regardless of an amplitude of current.

### DISCLOSURE

### Technical Problem

An object of the present invention is to provide an apparatus and method capable of capacity fade and power deterioration regardless of an amplitude of a current.

Further, another object of the present invention is to provide an apparatus and method capable of measuring capacity fade in real time.

In addition, yet another object of the present invention is to provide an apparatus and method capable of simply measuring capacity fade.

### Technical Solution

In one general aspect, an apparatus for measuring battery capacity fade includes: at least one battery used in a hybrid vehicle, a plug-in hybrid electric vehicle or an electric vehicle; a sensing unit sensing current, voltage and temperature of the at least one battery; a data processing unit measuring voltage and current data from the sensing unit if the current is constant current in a charging period and state of charge (SOC) is in a predetermined region; and a calculating unit setting at least two points on the voltage data and applying the voltage data corresponding to the at least two points to an equivalent circuit model of the at least one batter, to calculate faded capacity.

The apparatus may further include a memory unit to store voltage, current, a capacity fade and a moving average faded capacity.

The calculating unit may sum up the faded capacities stored in a predetermined period in which the vehicle travels to calculate a moving average faded capacity.

In another general aspect, a method for measuring battery capacity fade includes: determining whether a current flowing through at least one battery used in a plug-in hybrid electric vehicle or an electric vehicle is a constant current in a charging period or not; determining whether state of charging (SOC) is in a predetermined region or not if the current is a constant current in the charging period; measuring current and voltage data of the at least one battery if the SOC is in the predetermined region; setting at least two points on the measured voltage data; and applying the voltage data corresponding to the at least two points to an equivalent circuit model of the at least one battery to calculate a fade capacity.

The method may further include summing up the faded capacities stored in a predetermined period in which the vehicle travels to calculate a moving average faded capacity.

The faded capacities may be calculated using

$$Q = \frac{1}{36 {a}_{1}} \cdot \frac{Δ t}{Δ V}$$

where a₁ denotes a gradient between an SOC and an electromotive force, Δt denotes a time interval between two points, and ΔV denotes a voltage difference, wherein the moving average faded capacity may be calculated using

MAQₙ=wₙQₙ+wₙ₋₁Qₙ₋₁+ . . . +wₙ₋ᵢ₊₁Qₙ₋ᵢ₊₁

where the sum of the weights

$${\sum }_{j = 1}^{i} {w}_{j} = 1 ,$$

and wherein MAQₙ is an average value of a sum of the faded capacities Q, which approximate a faded capacity.

The a₁ may have different values depending on characteristics and a temperature of a battery and may not vary even if the capacity fades.

The equivalent circuit model may be an electrical circuit representing the battery with parameters such as a total resistance R*, a current I, a terminal voltage V and an electromotive force Vo.

The method may further include calculating a state of health (SOH) of a battery.

The SOH may be expressed using

$$SOH = \frac{{MAQ}_{n}}{NC} 100 \%$$

where “NC” denotes a nominal capacity, and MAQₙ denotes moving average faded capacity.

### Advantageous Effects

According to the present invention, capacity fade and power deterioration can be measured regardless of an amplitude of a current in a constant pattern.

Further, according to the present invention, capacity fade can be measured in real time.

Further, according to the present invention, the capacity fade algorithm is usable in on-line applications, uses simple equations for calculating capacity fade, and requires much smaller amounts of data, so that it can be much simply designed compared to algorithms according to the related art.

### DESCRIPTION OF DRAWINGS

The above and other objects, features and advantages of the present invention will become apparent from the following description of preferred embodiments given in conjunction with the accompanying drawings, in which:

FIG. 1 is a block diagram for illustrating a system for measuring battery capacity fade according to the present invention;

FIG. 2 is a block diagram for illustrating the main controller unit (MCU) of FIG. 1;

FIG. 3 is a block diagram for illustrating the process of measuring battery faded capacity according to the present invention;

FIG. 4 is a circuit diagram of the equivalent circuit model in FIG. 3;

FIG. 5 is a flowchart for illustrating the process of measuring battery capacity fade according to an embodiment of the present invention;

FIG. 6 is a graph showing periods in which the process of measuring battery capacity according to an embodiment of the present invention is carried out; and

FIG. 7 is a graph showing the moving average faded capacity calculated by summing up the measured capacities using FIGS. 1 to 6 according to another embodiment of the present invention.

### DETAILED DESCRIPTION OF MAIN ELEMENTS

| | |
|---|---|
| 101~10n: BATTERY | 100: BATTERY PACK |
| 110: BMS UNIT | 111: VOLTAGE SENSING |
| 112: CURRENT SENSING UNIT | UNIT |
| 113: TEMPERATURE SENSING UNIT | |
| 120: MCU UNIT | |
| 130: MAMORY UNIT | |
| 140: VEHICLE CONTROLLER | |
| 121: DATA PROCESSING UNIT | |
| 122: CALCULATING UNIT | |

### BEST MODE

Hereinafter, an embodiment of the present invention will be described in detail with reference to the accompanying drawings.

FIG. 1 is a block diagram for illustrating a system for measuring battery capacity fade according to the present invention. The system mainly includes a battery pack 100, a battery management system unit 110 including sensing units 111 to 113 that sense voltage, current and temperature of the battery pack and a micro controller unit (MCU) 120 that receives data from the sensing unit 111 to 113 to measure capacity fade, and a vehicle controller 140 that receives measured faded capacity from the BMS unit 110. The functions and roles of these components will be described below.

The battery pack 100 includes batteries 101 to 10n connected to one another in series or in parallel and may be a hybrid battery such as a nickel-metal battery or a lithium-ion battery. It is apparent that, although the battery pack 100 includes one pack in the embodiment of the present invention for the sake of easy understanding, the battery pack 100 may include several sub packs.

The BMS unit 110 includes the sensing units 111 to 113 and the MCU 120 and serves to measure capacity fade of the battery pack 100. Specifically, the sensing units 111 to 113 include a voltage sensing unit 111, a current sensing unit 112, and a temperature sensing unit 113 to sense voltage, current and temperature of the batteries 101 to 10n in the battery pack 110, respectively.

It is apparent that the temperature sensing unit 113 may sense temperature of the battery pack 100 or the batteries 101 to 10n. Here, the current sensing unit 112 may be a hall current transformer (CT) that uses a hall element to measure current and outputs an analog current signal corresponding to the measured current. However, the present invention is not limited thereto but any other elements may be used as long as they can sense current.

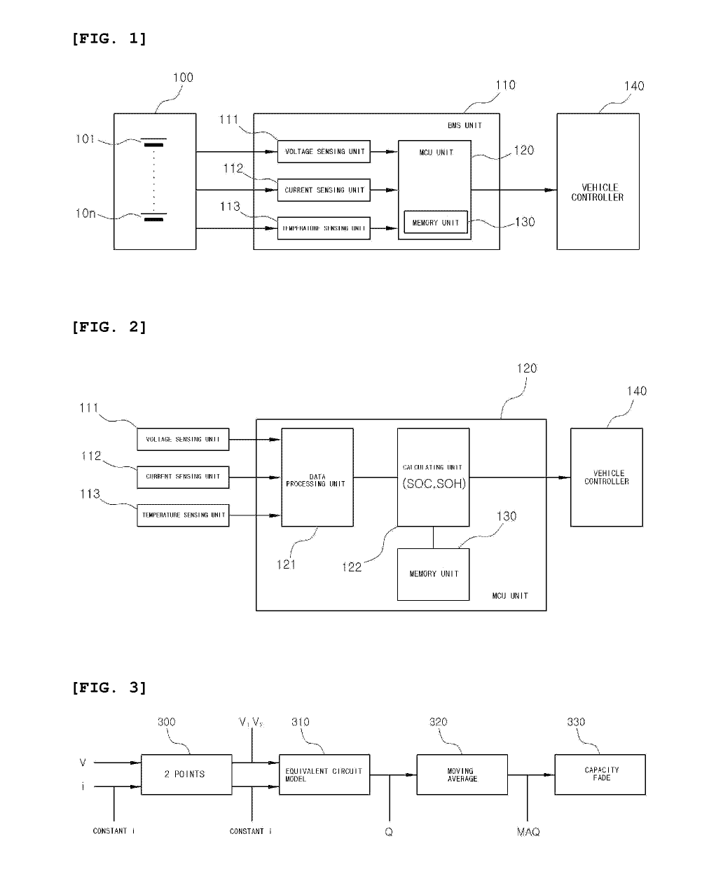

The micro controller unit (MCU) 120 receives voltage, current and temperature values of each of the batteries 101 to 10n sensed by the sensing unit 111 to 113 and estimates values of a state of charge (SOC) and a state of health (SOH) of corresponding batteries 101 to 10n in real time. Then, faded capacity of the batteries 101 to 10n and capacity fade stored in a certain period of time in which a vehicle travels are averaged to calculate a moving average faded capacity. The configuration of the MCU for such calculation process is shown in FIG. 2. A description thereon will be given below. Such values of the SOC and SOH, a faded capacity value and the like are stored in a memory unit 130 and transmitted to the vehicle controller 140.

The memory unit 130 may be provided in the MCU 120 or may be a separate memory. Accordingly, non-volatile memories such as a hard disk drive, a flash memory, a ferro-electric RAM (FRAM), a phase-change RAM (PRAM), a magnetic RAM (MRAM) may be used.

The vehicle controller 140 serves to maintain the performance of main systems necessary for traveling plug-in hybrid electric vehicles or electric vehicles so that they operate in the best condition. To this end, a controller area network (CAN) is used between the vehicle controller 140 and the MCU 120 to transmit the values of an SOC and an SOH of the batteries to the vehicle controller 140.

FIG. 2 is a block diagram for illustrating the MCU of FIG. 1. The MCU 120 may include a data processing unit 121 that processes data transmitted from the sensing unit 111 to 113, a calculating unit 122 that receives values of voltage, current and temperature from the data processing unit 121 and estimates the values of the SOC and SOH to obtain remaining capacity and lifespan shortening of the batteries, and a memory unit 130 that stores the values as data.

The calculating unit 122 receives the values of voltage, current and temperature of the batteries 101 to 10n sensed by the sensing unit 111 to 113 via the data processing unit 121, estimates in real-time the values of the SOC and SOH in a predetermined period from the values, and calculates the capacity of the batteries 101 to 10n and moving average faded capacity therefrom. It is apparent that these values are stored in the memory unit 130 in real time and transmitted to the vehicle controller 140.

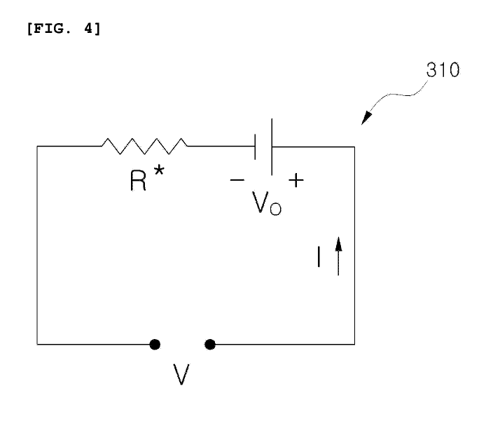

Now, the process of measuring battery faded capacity of the batteries 101 to 10n will be described. For the sake of easy understanding of the present invention, the process of measuring battery faded capacity is schematically shown in FIG. 3. FIG. 3 is a block diagram for illustrating the process of measuring battery faded capacity according to the present invention.

Typically, when a plug-in hybrid electric vehicle or an electric vehicle is parked at night, a battery in the vehicle is charged through an electric plug. In this case, the battery is charge from a low SOC to a very high SOC, during which faded capacity of the battery is calculated.

This is done by a battery model which is a simple equivalent circuit model of a complex battery model. An example of an equivalent circuit model is shown in FIG. 4. That is, FIG. 4 is a circuit diagram of the equivalent circuit model in FIG. 3. As shown in FIG. 4, total resistance R* is introduced in replace of the complex RC circuit and internal resistance R₀, and capacity fade is measured by developing the model. The parameters of the equivalent circuit model are described in Table 1 below.

TABLE 1

| | |
|---|---|
| I | Current (−: charge, +: discharge) |
| V | Terminal voltage |
| Vₒ | Open circuit voltage |
| R | Total resistance |

Referring to FIG. 3, data about the battery is collected if an SOC enters a predetermined region. Here, current I is constant current and thus is constant while voltage V varies in real time. Accordingly, two or more voltage points, e.g., V₁ and V₂ are considered to set a period (300). By applying these two points to the equivalent circuit model (310), faded capacity Q is calculated. In addition, by summing up faded capacity Q during the travel of a vehicle, moving average faded capacity is calculated (320). Based on the above, it may be possible to determine whether the state of the battery is in a capacity fade state.

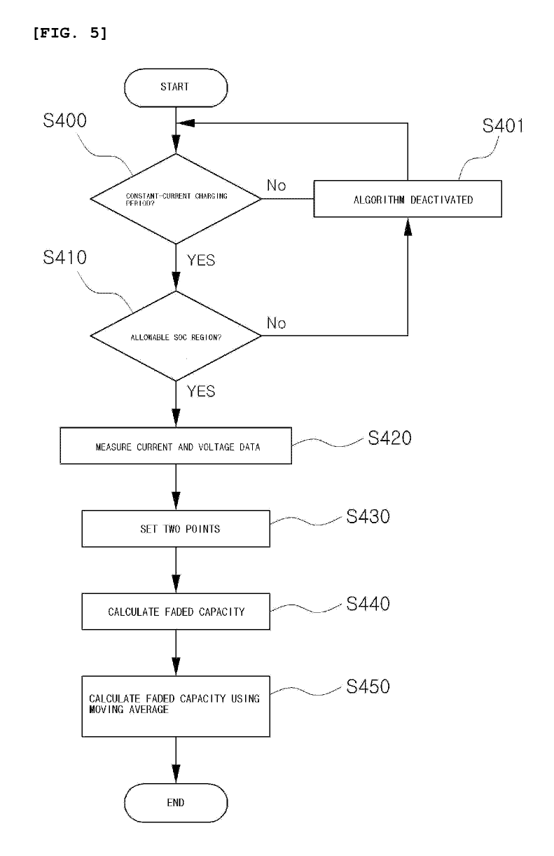

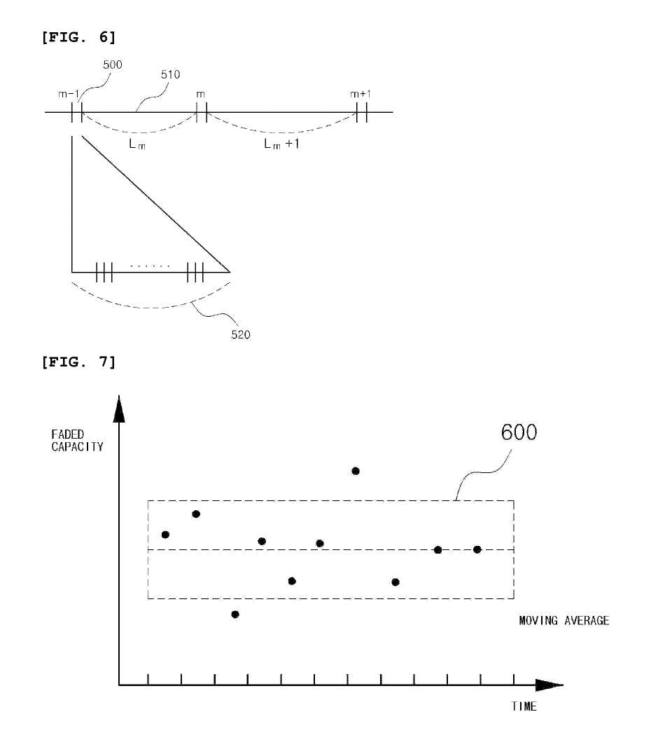

Now, the process of measuring battery capacity fade will be described in detail with reference to FIGS. 5 and 6. FIG. 5 is a flowchart for illustrating the process of measuring battery capacity fade according to the present invention. Prior to describing the process of measuring battery capacity fade, let us assume the following:

First, it is assumed that there is no variation in current because constant current should flow at the time of charging. Second, it is assumed that an SOC in the intermediate region has linear relationship with the electromotive force.

Third, it is assumed that the total resistance has little variation in a charging period so that it may be regarded as a constant value. Finally, it is assumed that there is little variation in the electromotive force curve even if capacity fade occurs.

The algorithm illustrated by the flowchart in FIG. 5 may be initiated when a plug-in hybrid electric vehicle or an electric vehicle is charged. This is shown in FIG. 6. FIG. 6 is a graph showing periods in which the process of measuring battery capacity according to an embodiment of the present invention is carried out. That is, the periods Lm and Lm+1 510 are charging periods, whereas the periods before Lm, between Lm and Lm+1, and after Lm+1 are data collecting periods 50. This data collecting periods 510 have constant current periods consisting of n data pieces.

Therefore, the algorithm illustrated by the flowchart in FIG. 5 is activated in the data collecting periods 510 to collect current and voltage data pieces. It is apparent that data pieces are collected at a predetermined time interval. The predetermined time interval may range from hours to days and need not be regular.

That is, the MCU (120 in FIGS. 1 and 2) may determine whether a plug-in hybrid electric vehicle or an electric vehicle is in a constant-current charging period (S400). If so, then it is determined whether an SOC is in a predetermined region (S410).

If the vehicle is not in a constant-current charging period or an SOC is not in a predetermined region, the algorithm in FIG. 5 is not activated (S401).

The collecting of current and voltage data pieces is initiated as soon as an SOC comes in the predetermined region and measuring is finished when an SOC exits the predetermined region. At this time, total current data is required since it is necessary to check if current is flowing constantly. Further, if it is checked that current is flowing constantly, voltage corresponding to the current is also preserved.

Once the current and voltage data pieces are collected, capacity is estimated through the equivalent circuit model. That is, a basic equivalent circuit model is used. However, as shown in FIG. 4, the equivalent circuit model introduces a total resistance R* in which an internal resistance R₀ and an RC circuit which may be used for explaining polarization phenomenon are combined.

The equation corresponding to the model is shown below. It can be seen that the equations used in modeling the equivalent circuit model may be given as follows:

V=V_{O}+IR* (1)

Here, two points, point 1 and point 2 are set as follows (S430):

V₁=V_{0,1}+I₁R₁* (2)

V₂=V_{0,2}+I₂R₂* (3)

By subtracting Equation 1 from Equation 2, the followings are obtained.

V₂−V₁=V_{0,2}−V_{0,1}+I₂R₂*−I₁R₁* (4)

∴ΔV=ΔV₀+(I₂R₂*−I₁R₁*) (5)

Here, current is equal on the assumption that constant-current charging is performed. In addition, R* is also equal on the assumption that internal resistance is constant during the charging.

Therefore, Equation 5 may be expressed in Equation 6 below:

∴ΔV=ΔV₀ (6)

Here, electromotive force V₀ is calculated as a function of an SOC. Here, in the intermediate region, the relationship between the electromotive force (substituted with open circuit voltage (OCV) when a battery is in a stable condition with no load) and an SOC may be linear as shown in Table 2 below.

This may be expressed as Equation 7 below:

SOC=a₁V₀+a₂ (7)

where the values of “a” are different depending on the characteristic and temperature of the battery. Further, it is assumed that a₁ does not vary even if capacity fade occurs. Here again, point 1 and point 2 may be set as follows:

SOC₁=a₁V_{0,1}+a₂ (8)

SOC₂=a₁V_{0,2}+a₂ (9)

By calculating the difference between Equation 8 and Equation 9, the following is obtained.

∴ΔSOC=a₁ΔV₀ (10)

Equation 6 and Equation 10 may produce the following relationship:

∴ΔSOC=a₁ΔV (11)

Incidentally, the algorithm of the flowchart in FIG. 5 is activated when charging is performed using constant current. Therefore, the time period is short and current is constant, so that calculation of an SOC is performed using Ah counting, which may expressed as Equation 12 below:

$${SOC}_{2} = {SOC}_{1} + \frac{{\int }_{{t}_{1}}^{{t}_{2}} I d t}{Q} \cdot \frac{100}{3600} \qquad ( 12 )$$

Where “100” refers to 100 percent in unit of SOC and “3600” refers to 1 hour in seconds.

Since current is constant, Ah counting may be represented by a multiple of current and time. Accordingly, the above equation may be expressed as Equation 13 below:

$$∴ Δ SOC = \frac{{\int }_{{t}_{1}}^{{t}_{2}} I d t}{36 Q} = \frac{I ( {t}_{2} - {t}_{1} )}{36 Q} \qquad ( 13 )$$

where “Q” denotes current battery capacity.

Equation 11 and Equation 13 may produce the following equation (S440):

$$Q = \frac{I}{36 {a}_{1}} \cdot \frac{Δ t}{Δ V} \qquad ( 14 )$$

Using the equation, current battery capacity may be measured. That is, if a time interval between current and points, a voltage difference, and a gradient between an SOC and the electromotive force are known, capacity fade of the battery may be measured in real time.

Once the battery capacity is calculated, the capacity value is stored in real time and may be summed up to obtain moving average faded capacity (S450). Specifically, a capacity is calculated as described with reference to FIGS. 1 to 6, and the capacity is stored in real time.

In this regard, since battery capacity fade occurs over a long period of time, a change in a day may not be noticeable. For this reason, a resulting capacity is obtained using the moving average value so as to avoid noise from occurring.

Therefore, the moving average value is to measure an optimal value by averaging previous n values for the measured capacities. In this example, in order to avoid noise from occurring, values of the measured capacity except for the maximum and minimum values are averaged.

For averaging, the closer to current measuring a value is, the more it is weighted. This may be expressed as Equation 15 below:

MAQₙ=wₙQₙ+wₙ₋₁Qₙ₋₁+ . . . +wₙ₋ᵢ₊₁Qₙ₋ᵢ₊₁ (15)

where

$${\sum }_{j = 1}^{i} {w}_{j} = 1$$

and “MAQ” denotes the value of Q through the moving average. By using Equation 15, the moving average faded capacity may be determined.

According to the manner described above, the lifespan (capacity) of a battery in a plug-in hybrid electric vehicle or an electric vehicle can be measured in real time. This is because there are continuous charging periods in a plug-in hybrid electric vehicle or an electric vehicle in which capacity fade may be calculated.

Here, state of health (SOH) of a battery may be defined as follows:

$$SOH = \frac{{MAQ}_{n}}{NC} 100 \% \qquad ( 16 )$$

where “NC” denotes a nominal capacity, and MAQₙ denotes moving average faded capacity.

For the sake of easy understanding of the present invention, a graph is shown in FIG. 7 in which the moving average faded capacity is quantified.

That is, FIG. 7 is a graph which shows the moving average faded capacity calculated by summing up the measured capacities using FIGS. 1 to 6 according to another embodiment of the present invention. Referring to FIG. 7, capacities are measured over time, and only faded capacities in the box 600 are calculated for the moving average. That is, the maximum and minimum values out of the box 600 are excluded.

Estimated values of Q in a hybrid vehicle or an electric vehicle according to FIGS. 1 to 7 may be represented as shown in Table 3 below.

That is, as shown in Table 3, the capacities fade over time.

The capacity fade algorithm described above with reference to FIGS. 1 to 7 may be applied to a capacity fade algorithm usable in on-line applications. Especially, the algorithm according to the present invention is very advantageous in that it is much simpler than existing models. The existing algorithms for measuring capacity fade are often too complicated to load on a battery management system. However, the algorithm according to the present invention may be conveniently used since it uses simple equations and requires much smaller amounts of data.

Although the exemplary embodiment of the present invention has been described above with reference to the accompanying drawings, it may be appreciated by those skilled in the art that the scope of the present invention is not limited to the above-mentioned exemplary embodiment, but may be variously modified. Therefore, the scope of the present invention is to be defined by the accompanying claims and their equivalents.

1. An apparatus for measuring battery capacity fade, comprising:
at least one battery used in a hybrid vehicle, a plug-in hybrid electric vehicle or an electric vehicle;
a sensing unit sensing current, voltage and temperature of the at least one battery;
a data processing unit measuring voltage and current data from the sensing unit if the current is constant current in a charging period and a state of charge (SOC) is in a predetermined region; and
a calculating unit setting at least two points on the voltage data and applying the voltage data corresponding to the at least two points to an equivalent circuit model of the at least one battery, to calculate faded capacity.

2. The apparatus of claim 1, wherein the calculating unit sums up the faded capacities stored in a predetermined period in which the vehicle travels to calculate a moving average faded capacity.

3. The apparatus of claim 2, further comprising a memory unit storing the voltage, the current, the faded capacities, and the moving average faded capacity.

4. The apparatus of claim 2, wherein the faded capacities are calculated using
$$Q = \frac{I}{36 {a}_{1}} \cdot \frac{Δ t}{Δ V}$$
where a₁ denotes a gradient between an SOC and an electromotive force, Δt denotes a time interval between two points, and ΔV denotes a voltage difference, and
wherein the moving average faded capacity is calculated using
MAQₙ=wₙQₙ+wₙ₋₁Qₙ₋₁+ . . . +wₙ₋ᵢ₊₁Qₙ₋ᵢ₊₁
where a sum of the weights
$${\sum }_{j = 1}^{i} {w}_{j} = 1 ,$$
and wherein MAQₙ is an average value of a sum of the faded capacities Q, which approximate a faded capacity.

5. The apparatus of claim 4, wherein a₁ has different values depending on characteristics and a temperature of a battery and does not vary even if the capacity fades, and wherein the equivalent circuit model is an electrical circuit representing the battery with parameters such as a total resistance R*, a current I, a terminal voltage V and an electromotive force Vo.

6. A method for measuring battery capacity fade, comprising:
determining whether a current flowing through at least one battery used in a plug-in hybrid electric vehicle or an electric vehicle is a constant current in a charging period or not;
determining whether a state of charging (SOC) is in a predetermined region or not if the current is a constant current in the charging period;
measuring current, voltage and temperature data of the at least one battery if the SOC is in the predetermined region;
setting at least two points on the measured voltage data; and
applying the voltage data corresponding to the at least two points to an equivalent circuit model of the at least one battery to calculate a fade capacity.

7. The method of claim 6, further comprising summing up the faded capacities stored in a predetermined period in which the vehicle travels to calculate a moving average faded capacity.

8. The method of claim 7, wherein the faded capacities are calculated using
$$Q = \frac{I}{36 {a}_{1}} \cdot \frac{Δ t}{Δ V}$$
where a₁ denotes a gradient between an SOC and an electromotive force, Δt denotes a time interval between two points, and ΔV denotes a voltage difference, and
wherein the moving average faded capacity is calculated using
MAQₙ=wₙQₙ+wₙ₋₁Qₙ₋₁+ . . . +wₙ₋ᵢ₊₁Qₙ₋ᵢ₊₁
where a sum of the weights
$${\sum }_{j = 1}^{i} {w}_{j} = 1 ,$$
and wherein MAQₙ is an average value of a sum of the faded capacities Q, which approximate a faded capacity.

9. The method of claim 8, wherein a₁ has different values depending on characteristics and a temperature of a battery and does not vary even if the capacity fades when an SOC of the battery is in the predetermined region, and wherein the equivalent circuit model is an electrical circuit representing the battery with parameters such as a total resistance R*, a current I, a terminal voltage V and an electromotive force Vo.

10. The method of claim 8, further comprising calculating a state of health (SOH) of a battery, wherein the SOH is calculated using
$$SOH = \frac{{MAQ}_{n}}{NC} 100 \%$$
where NC denotes a nominal capacity and MAQₙ denotes a moving average faded capacity.

11. The apparatus of claim 1, further comprising a memory unit storing the voltage, the current, the faded capacities, and the moving average faded capacity.

12. The apparatus of claim 1, wherein the faded capacities are calculated using
$$Q = \frac{I}{36 {a}_{1}} \cdot \frac{Δ t}{Δ V}$$
where a₁ denotes a gradient between an SOC and an electromotive force, Δt denotes a time interval between two points, and ΔV denotes a voltage difference, and
wherein the moving average faded capacity is calculated using
MAQₙ=wₙQₙ+wₙ₋₁Qₙ₋₁+ . . . +wₙ₋ᵢ₊₁Qₙ₋ᵢ₊₁
where a sum of the weights
$${\sum }_{j = 1}^{i} {w}_{j} = 1 ,$$
and wherein MAQₙ is an average value of a sum of the faded capacities Q, which approximate a faded capacity.

13. The method of claim 6, wherein the faded capacities are calculated using
$$Q = \frac{I}{36 {a}_{1}} \cdot \frac{Δ t}{Δ V}$$
where a₁ denotes a gradient between an SOC and an electromotive force, Δt denotes a time interval between two points, and ΔV denotes a voltage difference, and
wherein the moving average faded capacity is calculated using
MAQₙ=wₙQₙ+wₙ₋₁Qₙ₋₁+ . . . +wₙ₋ᵢ₊₁Qₙ₋ᵢ₊₁
where a sum of the weights
$${\sum }_{j = 1}^{i} {w}_{j} = 1 ,$$
and wherein MAQₙ is an average value of a sum of the faded capacities Q, which approximate a faded capacity.
